(19) United States
(12) Patent Application Publication
(10) Pub. No.: US 2026/0169397 A1
(43) Pub. Date: Jun. 18, 2026

(54) OPTICAL SYSTEM FOR MICROLITHOGRAPHY AND SENSOR ADAPTER

(71) Applicant: Carl Zeiss SMT GmbH, Oberkochen (DE)

(72) Inventors: Kristian MAUSER, Aalen (DE); Ole FLUEGGE, Unterschneidheim (DE); Marc Hill, Gersheim (DE)

(21) Appl. No.: 19/531,264

(22) Filed: Feb. 5, 2026

Related U.S. Application Data
(63) Continuation of application No. PCT/EP2024/067118, filed on Jun. 19, 2024.

(30) Foreign Application Priority Data
Aug. 23, 2023 (DE) 10 2023 208 047.8

(51) Int. Cl. G03F 7/00

(52) U.S. Cl. CPC G03F 7/70825; G03F 7/70258; G03F 7/7085

(57) ABSTRACT

An an optical system for microlithography, such as a projection lens, comprises: an optical element; a manipulator for moving the optical element; and at least one sensor for detecting a movement of the optical element, such as for detecting a position of the optical element. The sensor is mounted on a sensor adapter having a sensor housing, which is installed in the optical system via a releasable connection. A sensor adapter for an optical system for microlithography, such as an optical system, comprises: a sensor for detecting a movement of an optical element, such as for detecting a position of an optical element; and a sensor housing, which is designed for installation in the optical system via a releasable connection.

### CROSS-REFERENCE TO RELATED APPLICATIONS

The present application is a continuation of, and claims benefit under 35 USC 120 to, international application No. PCT/EP 2024/067118, filed Jun. 19, 2024, which claims benefit under 35 USC 119 of German Application No. 10 2023 208 047.8, filed Aug. 23, 2023. The entire disclosure of each of these applications is incorporated by reference herein.

### FIELD

The disclosure relates to an optical system for microlithography, such as a projection lens for a projection exposure apparatus, which comprises: at least one optical element; a manipulator for moving the optical element; and at least one sensor for detecting the movement of the optical element, such as for detecting a position of the optical element. The disclosure also relates to a sensor adapter.

### BACKGROUND

An optical system for microlithography can be for example a projection lens for a projection exposure apparatus. Projection exposure apparatuses for microlithography are used for the photolithographic production of semiconductor components and other patterned components. A pattern on a mask, also called reticle, is projected onto a substrate, also called wafer, which is usually coated with a light-sensitive layer. For this purpose, such a projection exposure apparatus comprises a projection lens having a plurality of optical elements, which can be designed for example as lens elements, mirrors, gratings or plane-parallel plates. The optical elements are mounted by way of mounts in a housing of the projection lens.

During operation of the optical system, the optical elements heat up, which causes the imaging properties of the optical system to change. This may lead to aberrations of the wavefront propagating in the optical system and thus to a deterioration in the imaging quality. It is known to use manipulators for moving and/or deforming optical elements in order to compensate for imaging aberrations attributable for example to heating or the like. Such manipulators are described for example in DE 199 01 295 A1 or DE 10 2009 054 868 A1.

DE 199 10 947 A1 describes a device for displacing an optical element along the optical axis, for example a lens element in a lens. The optical element is supported by a holding ring acted upon by an adjusting device with at least one adjusting drive. Sensors can be provided which measure or monitor a position and/or an orientation of the holding ring for the optical element in order to ascertain tilting of the holding ring.

Such sensors typically measure the position and/or the orientation of the optical element directly and are fixedly integrated or installed in the lens. If such a fixedly integrated sensor fails when the optical system has been installed at a customer's site, the entire optical system, e.g. the projection lens, is usually disassembled in order to replace the sensor. The replacement generally cannot be performed at the customer's site, but rather involves transport of the projection lens to a repair workshop, disassembly of the projection lens, the repair itself, subsequent assembly, transport back to the customer and reinstallation of the projection lens at the customer's site. The entire replacement process is therefore generally very time-consuming and associated with high costs. In order to reduce the likelihood of replacement, a plurality of redundant sensors can be fixedly integrated in the optical system.

In order to simplify the replacement process, the use of an external sensor is possible, which indirectly determines the movement of the optical element with the aid of an actuating element or actuator of the manipulator, for example by measuring the position of an actuator plunger or the like. The replacement of such a sensor generally does not involve disassembly of the optical system. However, the indirect determination of the position of the optical element with such a sensor is typically not very precise. For example, there may be a displacement ratio between the actuator movement and the stroke during the movement of the optical element, which can result in the measurement range of the external sensor being many times larger than the stroke of the movement of the optical element. However, as the measurement range increases, the resolution of the sensor can decrease and the noise of the sensor signal can increase. Accordingly, the movement of the optical element is determined only with a comparatively high inaccuracy by such a sensor.

### SUMMARY

The disclosure seeks to provide an optical system for microlithography, for example a projection lens, having a sensor that allows the position of the optical element to be detected relatively precisely and that is relatively easily replaceable.

The disclosure provides an optical system for microlithography, such as a projection lens for a projection exposure apparatus, wherein a sensor is mounted on a sensor adapter having a sensor housing, which is installed or integrated in the optical system via a releasable connection.

The inventors propose to use, for detecting the movement of the optical element, a sensor which is arranged within a housing of the optical system, for example within an outer mount of the optical element. In order to allow relatively simple replacement of the sensor, the sensor is mounted on a sensor adapter, the sensor housing of which is integrated or installed in the optical system via a releasable connection. Releasing the connection makes it possible to remove the sensor together with the sensor adapter from the optical system and replace it in a relatively simple manner in the event of a sensor failure. In a simple case, the sensor adapter can comprise only the sensor and the sensor housing. In general, the sensor adapter has further components, for example electrical lines or the like, in order to transmit a measurement signal generated by the sensor or to supply the sensor with energy.

The optical system can be for example a projection lens for microlithography. The sensor adapter described here can be installed for example in a component of an optical system, for example of such a projection lens. The projection lens can be designed for different wavelengths, for example for a wavelength of 365 nm corresponding to the i-line of a mercury vapor lamp, for the DUV wavelength range, or for the VUV wavelength range with or without immersion. The optical element can be for example a lens element. The sensor can be used for example to measure a movement of the optical element in the form of a displacement of the optical element along its optical axis, a deformation of the optical element or—if a plurality of sensors are used—a tilting movement of the optical element.

The inventors have recognized that despite the generally small stroke of the order of magnitude of one millimeter (mm) or less which is typically generated during the movement of the optical element via the manipulator, fixed integration or fixed installation of the sensor in the optical system can be avoided. Even when the sensor is mounted on a releasably secured sensor housing—or sensor housing installed in the optical system—of a sensor adapter, sufficient precision is possible when detecting the movement of the optical element, i.e. the sensor, even when mounted on a sensor adapter, can be positioned precisely enough to allow the movement of the optical element to be detected with relatively high precision.

In one embodiment, the sensor housing has a connecting portion, which is releasably connected to an outer side of an optionally ring-shaped outer mount of the optical element. The releasable connection can be for example a screw connection. Other types of releasable connections are also possible, e.g. bayonet catches, plug or clamping connections, etc. The connecting portion can be a housing portion of the integral or multipartite sensor housing of the sensor adapter.

The connection on the connecting portion defines the orientation of the sensor adapter relative to the outer mount. The connecting portion can protrude laterally beyond an e.g. rod-shaped guide portion of the sensor adapter and can have for example a plurality of openings for the passage of screws or the like in order to connect the sensor adapter fixedly, but releasably to the outer mount. To remove the sensor from the optical system, an operator can release the sensor adapter from the outer side of the outer mount without the inner side of the outer mount having to be made accessible for this purpose, which would typically involve disassembling the optical system.

In one development, the outer mount can have a radially extending, continuous channel for inserting a measuring portion of the sensor housing, on which the sensor is mounted, into an interior of the outer mount. The sensor adapter, for example a generally rod-shaped guide portion of the sensor housing, the guide portion proceeding from the connecting portion, is inserted into the channel in order to position the measuring portion with the sensor in the interior of the outer mount, thus enabling the movement of the optical element arranged in the outer mount to be detected. The sensor adapter can be sealed vis-à-vis the channel with the aid of a seal, e.g. with the aid of an O-ring, but this is not mandatory.

In a development, the measuring portion of the sensor adapter protrudes beyond an inner side of the outer mount. In this case, the measuring portion of the sensor adapter projects into the interior of the outer mount in order to suitably position the sensor for detecting the movement of the optical element. For example, the sensor can be arranged at a small distance from a target surface for the detection of the movement of the optical element (see below).

In one embodiment, the sensor is designed as a non-contact sensor, for example as a non-contact position sensor. In principle, the movement of the optical element can be measured with the aid of various types of sensors. A non-contact measurement, for example a non-contact position measurement, is desirable in order to simplify the removal of the sensor from the optical system with the aid of the sensor adapter. The non-contact position sensor is typically a distance sensor. In this case, the position of the optical element can be determined on the basis of the distance between a sensor surface of the distance sensor and a target surface. For example, the position sensor or the distance sensor can be an optical sensor.

In one development of this embodiment, the non-contact sensor is designed as a capacitive distance sensor. A capacitive distance sensor can detect the distance between a sensor surface, which typically forms a first electrode, and a target surface, which typically forms a second electrode. It is desirable for distance measurement for the sensor surface and the target surface to be planar surfaces, but this is not mandatory. The distance measurement with the aid of a capacitive distance sensor is possible in a relatively precise manner even if the sensor surface is arranged at a small distance from the target surface of e.g. one mm or less.

In one development, the optical element is received in an optionally ring-shaped holder and the position sensor is designed for determining a distance between a sensor surface of the sensor and a target surface of the holder or of a component mounted on the holder, for example of a spacer. The holder is typically a holding ring that supports the optical element. During the movement of the optical element, the holding ring is typically moved as well, which is why the movement of the optical element can be detected by determining the distance between the holding ring or a component mounted, generally secured, on the holding ring and the sensor surface. The component mounted on the holder can be for example a spacer which compensates for an undesirable offset in the longitudinal direction of the optical system during the initial assembly of the optical system. However, the component that has the target surface of the sensor can also be some other component mounted on the holder.

In an embodiment, the manipulator is designed for moving the optical element along a longitudinal direction of the optical system, for example of the projection lens. The longitudinal direction of the optical system can be for example the direction of gravity, which hereinafter is also referred to as the Z-direction. The longitudinal direction of the optical system typically corresponds to the optical axis of the optical system or runs parallel to the optical axis of the optical system.

The manipulator can be used to move the optical element with a linear movement in the longitudinal direction of the optical system or along the optical axis, but it is also possible in principle for the manipulator to additionally tilt the optical element during the movement along the longitudinal direction. For this purpose, the manipulator can have a plurality of actuating elements which act upon the optical element and which can be moved independently of one another along the longitudinal direction of the optical system. For this purpose, the manipulator can have for example one or more actuating elements which act upon the holder described further above in order to move it in the longitudinal direction of the optical system.

The actuating element(s) of the manipulator can be mounted on a typically ring-shaped supporting element that forms a part of the outer mount or is mounted on the outer mount, generally on the inner side of the outer mount. There are a multitude of possibilities for the specific configuration of the manipulator. Merely by way of example, reference should be made to DE 199 01 295 A1, DE 10 2009 054 868 A1 and DE 199 10 947 A1 cited further above, which in their entirety are incorporated by reference in the content of this application.

In an embodiment, the sensor adapter has a plug connector for electrically contacting the sensor. The plug connector is typically mounted on that end of the sensor adapter at which the connecting portion is formed. The plug connector is signal-connected to the sensor e.g. via electrical lines running in the sensor adapter. With the aid of the plug connector, simple electronic contacting of the sensor can be effected in order to read it and/or to supply the sensor with energy.

In an embodiment, the optical system has at least three sensors, each mounted on a sensor adapter, for detecting the movement of the optical element. The three or more sensors are typically arranged in a manner distributed over the circumference of the optical element and make it possible in each case to detect the position of the optical element in the longitudinal direction of the optical system or along the optical axis. The three or more positions detected by the sensors can be used to determine a tilt of the optical element relative to a plane perpendicular to the longitudinal direction of the optical system. In the event that the manipulator has a plurality of mutually independently controllable actuating elements, the tilt can be corrected if it is undesirable, or the tilt can be suitably adapted.

The disclosure also relates to a sensor adapter for an optical system, for example for an optical system designed as described further above, comprising: a sensor for detecting a movement, for example for detecting a position, of the optical element, wherein the sensor adapter has a sensor housing, which is designed for installation in the optical system via a releasable connection.

The sensor adapter can be designed for example in the manner described further above in association with the optical system.

In one embodiment, the sensor housing has a connecting portion for releasable connection to an outer side of an optionally ring-shaped outer mount of the optical element. The releasable connection can be for example a screw connection.

The sensor housing can have a guide portion designed for insertion into an optionally radially extending, continuous channel of the outer mount in order to insert a measuring portion of the sensor adapter, on which the sensor is mounted, into an interior of the outer mount. The connecting portion, the typically rod-shaped guide portion, and the measuring portion form three portions of an integral or multipartite sensor housing of the sensor adapter.

In an embodiment, the sensor is designed as a non-contact sensor, such as a non-contact position sensor, for example as a capacitive distance sensor. As has been described further above, the use of a non-contact sensor facilitates the replacement of the sensor adapter.

In one embodiment, the sensor adapter has a plug connector for electrically contacting the sensor. The plug connector is typically mounted in the region of the connecting portion of the sensor adapter in order to be able to contact the plug connector from the outer side of the outer mount.

Further features and aspects of the disclosure are evident from the following description of exemplary embodiments of the disclosure with reference to the figures of the drawing, which show certain details regarding the disclosure, and from the claims. The individual features can be realized in each case individually by themselves or as a plurality in any desired combination in a variant of the disclosure.

Exemplary embodiments are illustrated in the schematic drawings and are explained in the following description.

### BRIEF DESCRIPTION OF THE DRAWINGS

In the figures:

FIG. 1 shows a schematic illustration of a DUV lithography apparatus comprising an illumination device and a projection lens;

FIGS. 2A-2B show a schematic illustration of a plan view of a ring-shaped outer mount of an optical element of the projection lens with one and respectively with three sensor adapters;

FIGS. 3A-3B show schematic sectional illustrations of the outer mount and of a sensor adapter during insertion and respectively after insertion into a channel of the outer mount; and

FIGS. 4A-4B show perspective illustrations of two sensor adapters with different geometries.

### EXEMPLARY EMBODIMENTS

In the following description of the drawings, identical reference signs are used for identical or functionally identical components.

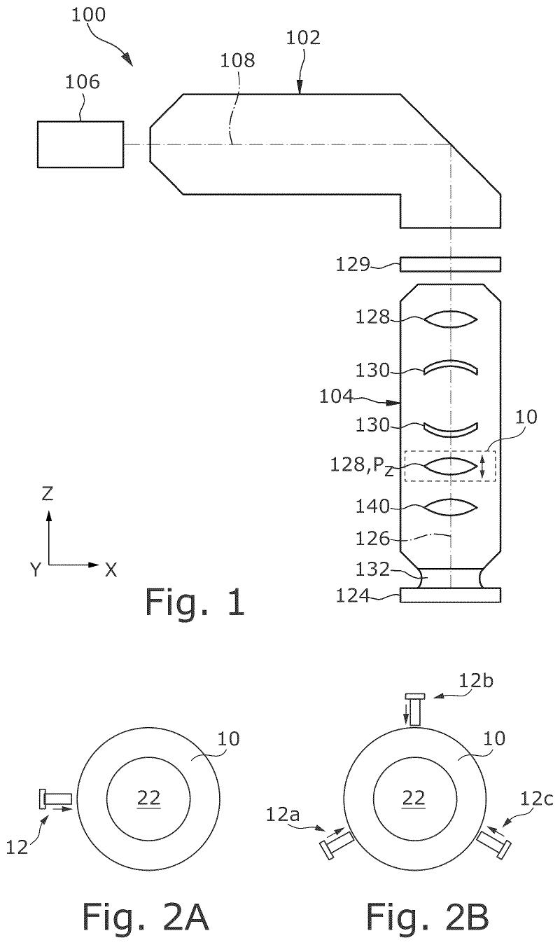

FIG. 1 shows a schematic view of a of a DUV projection exposure apparatus 100, which comprises a beam shaping and illumination device 102 and a projection lens 104. In this case, DUV stands for “deep ultraviolet” and denotes a wavelength of the working light of between 30 nm and 370 nm. The DUV projection exposure apparatus 100 comprises a DUV light source 106. For example, an ArF excimer laser that emits radiation 108 in the DUV range at for example 193 nm can be provided as the DUV light source 106.

The beam shaping and illumination device 102 illustrated in FIG. 1 directs the DUV radiation 108 onto a photomask 129. The photomask 129 is designed as a transmissive optical element and can be arranged outside the beam shaping and illumination device 102 and the projection lens 104. The photomask 129 has a structure of which a reduced image is projected onto a wafer 124 or the like via the projection lens 104.

The projection lens 104 has a plurality of lens elements 128, 140 and/or mirrors 130 for imaging the photomask 129 onto the wafer 124. In this case, individual lens elements 128, 140 and/or mirrors 130 of the projection lens 104 can be arranged symmetrically in relation to the optical axis 126 of the projection lens 104. It should be noted that the number of lens elements and mirrors of the DUV projection exposure apparatus 100 is not restricted to the number illustrated. More or fewer lens elements and/or mirrors can also be provided. Furthermore, the mirrors are generally curved on their front side for beam shaping purposes.

An air gap between the last lens element 140 and the wafer 124 can be replaced by a liquid medium 132 having a refractive index>1. The liquid medium 132 can be high-purity water, for example. Such a set-up is also referred to as immersion lithography and has an increased photolithographic resolution.

The optical elements 128, 130, 140 of the projection lens 104 are each received in an outer mount. One such outer mount 10 for receiving an optical element in the form of a lens element 128 is illustrated using dashed lines in FIG. 1. The ring-shaped outer mount 10 is shown in a plan view in FIGS. 2A-2B and is used for mounting one sensor adapter 12 in FIG. 2A and for mounting three sensor adapters 12a-c in FIG. 2B. The sensor adapters 12, 12a-c are inserted into the outer mount 10 in the radial direction in each case during assembly, as is indicated by arrows in FIGS. 2A-2B.

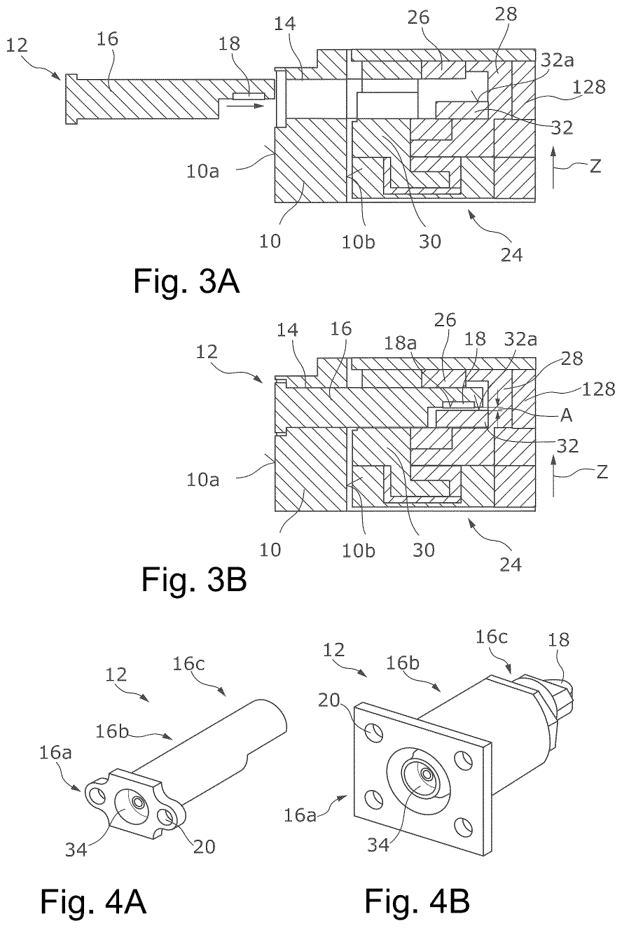

FIG. 3A shows the sensor adapter 12 and the outer mount 10 from FIG. 2A in a longitudinal section. As can be discerned in FIG. 3A, the sensor adapter 12, during assembly in the direction of the arrow corresponding to the radial direction, is inserted into a continuous channel 14 extending in the outer mount 10, the channel extending in the radial direction, until the sensor adapter 12 reaches a measurement position illustrated in FIG. 3B. In the example shown, the radially extending channel 14 is designed in the form of a cylindrical through hole, but this is not mandatory.

The sensor adapter 12 has a sensor housing 16 having a rod-shaped or cylindrical guide portion 16b, a connecting portion 16a adjacent to the guide portion 16b at a first end of the sensor adapter 12, and a measuring portion 16c adjacent to the guide portion 16b at a second end of the sensor adapter 12, as is shown in FIGS. 4A-4B. A sensor 18 is mounted on the measuring portion 16c of the sensor adapter 12.

The sensor adapter 12 is inserted into the channel 14 of the outer mount 10 with the measuring portion 16c ahead during assembly. In the example shown, the rod-shaped guide portion 16b is of circular-cylindrical design and serves to guide the sensor adapter 12 during insertion into the channel 14 of the outer mount 10. The connecting portion 16a protrudes laterally beyond the guide portion 16b and is designed for the releasable connection of the sensor adapter 12 to an outer side 10a of the outer mount 10. For this purpose, the connecting portion 16a has two through holes 20 in the sensor adapter 12 illustrated in FIG. 4A and four through holes 20 in the sensor adapter 12 illustrated in FIG. 4b. The through holes 20 are each used to receive a screw which is screwed to the outer mount 10. It goes without saying that the connecting portion 16a can also be designed differently than illustrated in FIGS. 4A-4B.

As has been described further above, the sensor adapter 12, more precisely the sensor housing 16, is secured or fixed to the outer side 10a of the outer mount 10 with the aid of a screw connection at the connecting portion 16a and is oriented in the radial direction in the process. For the centering of the sensor adapter 12 in the channel 14 of the outer mount 10, centering holes or centering pins can be used, which are not illustrated pictorially. It is possible to seal the sensor adapter 12 with the aid of a seal, e.g. with an O-ring, with respect to the channel 14 in order to seal an interior 22 of the outer mount 10, the interior being illustrated in FIGS. 2A-2B, vis-à-vis the surroundings. However, such sealing is not mandatory.

In the measurement position illustrated in FIG. 3B, the sensor 18 protrudes beyond an inner side 10b of the outer mount 10 and projects into the interior 22 of the outer mount 10. In the example shown, the sensor 18 is designed as a position sensor and is used to detect the movement of the lens element 128 in the Z-direction. The Z-direction runs parallel to the optical axis 126 of the projection lens 104 and forms the longitudinal direction of the projection lens 104. The movement of the lens element 128 in the Z-direction is generated with the aid of a manipulator 24 indicated in FIGS. 3A-3B. In the example shown, the manipulator 24 serves for moving the lens element 128 in the longitudinal direction Z of the projection lens 104, without causing a tilt of the lens element 128 in the process. The manipulator 24 can be designed in various ways, for example as described in DE 199 01 295 A1, DE 10 2009 054 868 A1 or DE 199 10 947 A1 cited in the introduction. The manipulator 24 can alternatively be designed to generate a tilt of the lens element 128.

In the example shown, the manipulator 24 has an actuating element 26, which acts on a ring-shaped holder or a holding ring 28 used to support the lens element 128. The actuating element 26 of the manipulator 24 is mounted on a supporting ring 30 secured on the inner side 10b of the outer mount 10. The actuating element 26 can be designed in various ways and causes a linear movement of the lens element 128 in the Z-direction, i.e. a change in the Z-position P_{Z} of the lens element 128, as indicated by a double-headed arrow in FIG. 1. The maximum stroke during the movement of the lens element 128 in the Z-direction with the aid of the manipulator 24 is of the order of magnitude of approx. +/−1 mm.

The sensor 18 is used to detect the Z-position P_{Z} of the lens element 128 and is designed as a non-contact distance sensor, more precisely as a capacitive distance sensor. In the example shown, the sensor 18 is designed to detect a distance A in the Z-direction between a planar sensor surface 18a of the sensor 18 and a planar target surface 32a, which forms the top side of a spacer 32 mounted or secured on the holding ring 28. The spacer 32 is used during the initial assembly of the projection lens 104 in order to compensate for an undesirable offset of the lens element 128 or the mechanical systems (outer mount, mechanisms, etc.) in the Z-direction. The spacer 32 is moved by the manipulator 24 jointly with the holding ring 28 in the Z-direction, so that the Z-position P_{z} of the lens element 128 can be detected on the basis of the distance A in the Z-direction between the sensor surface 18a and the target surface 32a. It goes without saying that, in contrast to the illustration shown in FIGS. 3A-3B, the sensor 18 can also be designed to determine the distance A to a target surface on the holding ring 28.

The sensor 18 directly detects the movement or displacement of the ring-shaped holder 28 in the Z-direction. This is desirable because the maximum stroke during the movement of the lens element 128 in the Z-direction with the aid of the manipulator 24 is very small and the sensor 18 can therefore detect the Z-position P_{Z} of the lens element 128 very precisely. For the direct measurement of the Z-position P_{Z}, the sensor 18 is positioned in the interior 22 of the outer mount 10. With the aid of the sensor adapter 12, the sensor 18 can be removed from the interior 22 of the outer mount 10 without the projection lens 104 having to be disassembled for this purpose.

As can be discerned in FIGS. 4A-4B, the sensor adapter 12 has a plug connector 34, which makes it possible to electrically contact the sensor 18. For establishing the electrical connection between the plug connector 34 and the sensor 18, electronic lines not illustrated pictorially are mounted in the sensor housing 16 of the sensor adapter 12. The sensor 18 can be supplied with energy via the plug connector 34 and the distance A or the capacitance detected by the distance sensor 18 between the sensor surface 18a and the target surface 32a can be read out via the plug connector 34. The provision of a plug connector 34 on the sensor adapter 12 is not mandatory.

With the aid of the three sensor adapters 12a-c illustrated in FIG. 2B, on which three sensors not illustrated pictorially are mounted, a Z-position can be determined at three positions in the circumferential direction of the lens element 128. On the basis of this information, a tilt of the lens element 128, i.e. a deviation of the orientation of the lens element 128 from a plane perpendicular to the Z-direction, can be calculated or determined. It goes without saying that for this purpose the three sensor adapters 12a-c need not necessarily be arranged at equal distances in the circumferential direction, as illustrated in FIG. 2B, but rather can also be arranged at different distances in the circumferential direction.

What is claimed is:

1. An optical system comprising:
an optical element;
a manipulator configured to move the optical element;
a distance sensor configured to detect a movement of the optical element; and
a sensor adaptor comprising a sensor housing;
wherein:
the distance sensor is supported by the sensor adaptor;
the sensor adaptor is releasably connected within the optical system; and
the optical system is a microlithography optical system.

2. The optical system of claim 1, further comprising an outer mount receiving the optical element, wherein the sensor housing comprises a connecting portion releasably connected to an outer side of the outer mount.

3. The optical system of claim 2, wherein the outer mount is ring-shaped.

4. The optical system of claim 2, wherein:
the sensor housing comprises a measuring portion supporting the distance sensor;
the outer mount comprises a continuous channel;
the measuring portion of the sensor housing is inserted into an interior of the outer mount via the continuous channel of the outer mount.

5. The optical system of claim 4, wherein the measuring portion of the sensor housing protrudes beyond an inner side of the outer mount.

6. The optical system of claim 1, wherein the distance sensor comprises a non-contact distance sensor.

7. The optical system of claim 1, wherein the distance sensor comprises a capacitive distance sensor.

8. The optical system of claim 1, further comprising a holder receiving the optical element, wherein the distance sensor is configured to determine a distance between a sensor surface of the distance sensor and a target surface of the holder.

9. The optical system of claim 1, further comprising a holder receiving the optical element, wherein the distance sensor is configured to determine a distance between a sensor surface of the distance sensor and a component mounted on the holder.

10. The optical system of claim 9, wherein the component comprises a spacer.

11. The optical system of claim 1, wherein the manipulator is configured to move the optical element along a longitudinal direction of the optical system.

12. The optical system of claim 1, wherein the sensor adapter comprises a plug connector electrically contacting the distance sensor.

13. The optical system of claim 1, comprising three distance sensors, wherein each distance sensor is supported by a corresponding sensor adapter releasably connected within the optical system, and each distance sensor is configured to detect movement of the optical element.

14. The optical system of claim 1, wherein the optical system comprises a microlithography projection lens.

15. The optical system of claim 1, wherein the distance sensor is configured to determine a position of the optical element.

16. An apparatus, comprising:
an illumination device configured to illuminate structures of a photomask; and
a projection lens configured to project a reduced image of the illuminated structures, the projection lens comprising:
an optical element;
a manipulator configured to move the optical element;
a distance sensor configured to detect a movement of the optical element; and
a sensor adaptor comprising a sensor housing,
wherein the distance sensor is supported by the sensor adaptor, and the sensor adaptor is releasably connected within the projection lens.

17. A sensor adapter, comprising:
a sensor housing configured to be releasably connected within a microlithography optical system; and
a sensor configured to detect a movement of an optical element,
wherein the sensor is supported by the sensor adapter.

18. The sensor adapter of claim 17, wherein the sensor housing comprises a connecting portion which is releasably connectable to an outer side of a mount receiving the optical element.

19. The sensor adapter of claim 18, wherein:
the sensor housing comprises a measuring portion supporting the distance sensor;
the sensor housing comprises a guide portion configured to be inserted into a continuous channel of the outer mount so that the measuring portion of the sensor housing is in an interior of the outer mount.

20. The sensor adapter of claim 17, wherein the distance sensor comprises a non-contact distance sensor.
